(19) United States
(12) Patent Application Publication
(10) Pub. No.: US 2021/0114923 A1
(43) Pub. Date: Apr. 22, 2021

(54) SYSTEMS AND METHODS FOR ADHERING COPPER INTERCONNECTS IN A DISPLAY DEVICE

(71) Applicant: CORNING INCORPORATED, CORNING, NY (US)

(72) Inventors: MING-HUANG HUANG, ITHACA, NY (US); HOON KIM, HORSEHEADS, NY (US); ROBERT GEORGE MANLEY, VESTAL, NY (US); RAJESH VADDI, CORNING, NY (US); BIN ZHU, ITHACA, NY (US)

(21) Appl. No.: 17/047,838

(22) PCT Filed: Apr. 18, 2019
(86) PCT No.: PCT/US2019/028032

§ 371 Date: Oct. 15, 2020

Related U.S. Application Data
(60) Provisional application No. 62/809,963, filed on Feb. 25, 2019.
(60) Provisional application No. 62/660,677, filed on Apr. 20, 2018.

(51) Int. Cl. C03C 17/40; H01L 27/12; C03C 17/36; C03C 15/00

(52) U.S. Cl. CPC C03C 17/40; H01L 27/1262; C03C 2217/253; C03C 15/00; C03C 17/3655

(57) ABSTRACT

Embodiments are related generally to conductive interconnects formed on substrates, and more particularly to a glass ceramic, or glass-ceramic substrate having copper interconnects disposed thereon.

### CROSS-REFERENCE TO RELATED APPLICATION

This application claims the benefit of priority under 35 U.S.C. § 119 of U.S. Provisional Application Ser. No. 62/660677 filed on Apr. 20, 2018 and U.S. Provisional Application Ser. No. 62/809963 filed on Feb. 25, 2019, the content of each of which are relied upon and incorporated herein by reference in its entirety.

### FIELD

This description pertains to glass and/or ceramic surfaces and articles having improved adhesion to copper.

### BACKGROUND

Glass, ceramic, and glass-ceramic substrates with are desirable for many applications, including for use as display tiles, interposers used as an electrical interface, RF filters, and/or RF switches. Glass substrates have become an attractive alternative to silicon and fiber reinforced polymers for such applications. That said, typical metals used to form interconnects do not adhere very well to glass substrates.

Hence, for at least the aforementioned reasons, there exists a need in the art for advanced systems and methods for adhering copper to glass, ceramic, and glass-ceramic materials.

### SUMMARY

Embodiments are related generally to substrates and conductive interconnects, and more particularly to a glass, ceramic, or glass-ceramic substrate having copper interconnects disposed thereon.

This summary provides only a general outline of some embodiments. The phrases “in one embodiment,” “according to one embodiment,” “in various embodiments”, “in one or more embodiments”, “in particular embodiments” and the like generally mean the particular feature, structure, or characteristic following the phrase is included in at least one embodiment, and may be included in more than one embodiment. Importantly, such phrases do not necessarily refer to the same embodiment. Many other embodiments will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a schematic top perspective view of a prior art display;

FIGS. 2a-2c show interim display devices after application of respective processes for forming copper interconnects on a glass or glass-ceramic display substrate in accordance with some embodiments;

FIG. 3 is a flow diagram showing a method for forming copper interconnects on a glass or glass-ceramic display substrate in accordance with various embodiments;

FIGS. 4a-4d show interim display devices after application of respective processes for forming copper interconnects on a glass or glass-ceramic display substrate including expanding oxygen area on the surface of the substrate in accordance with other embodiments;

FIG. 5 is a flow diagram showing a method for forming copper interconnects on a glass or glass-ceramic display substrate including expanding oxygen area on the surface of the substrate using a leaching process in accordance with various embodiments;

FIG. 6 is a flow diagram showing another method for forming copper interconnects on a glass or glass-ceramic display substrate including expanding oxygen area on the surface of the substrate using an etching process in accordance with some embodiments;

FIGS. 7a-7d show interim display devices after application of respective processes for forming copper interconnects on a glass or glass-ceramic display substrate including a stop layer disposed over the surface of the substrate in accordance with some embodiments;

FIG. 8 is a flow diagram showing a method for forming copper interconnects on a glass or glass-ceramic display substrate including forming a stop layer over the surface of the substrate in accordance with one or more embodiments; and

FIGS. 9a-9e show interim display devices after application of respective processes for forming copper interconnects on a glass or glass-ceramic display substrate including expanding oxygen area on the surface of the substrate and forming a sealing layer disposed over the surface of the substrate in accordance with various embodiments.

### DETAILED DESCRIPTION

Embodiments are related generally to conductive interconnects formed on substrates, and more particularly to a glass ceramic, or glass-ceramic substrate having copper interconnects disposed thereon.

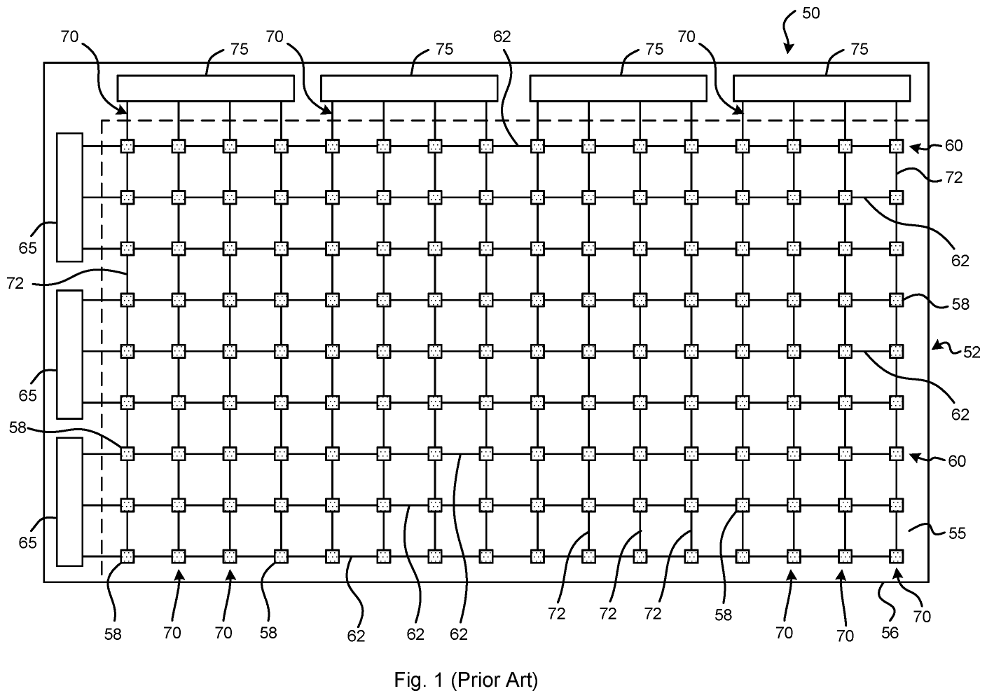

Turning to FIG. 1, a prior art display tile 50 is shown. Display tile 50 includes a first substrate 52 having a first surface 55 and an outer perimeter 56. The display tile 50 includes rows 60 of pixel elements and columns 70 of pixel elements 58. Each row 60 of pixel elements 58 is connected by a row electrode 62 and a plurality of columns 70 of pixel elements 58, and each column 70 of pixel elements 58 is connected by a column electrode 72. The display tile 50 further includes at least one row driver 65 that activates the rows 60 of pixel elements 58 and at least one column driver 75 that activates the columns 70 of pixel elements 58. In the prior art display tile 50, the row drivers 65 and the column drivers 75 are located on the first surface 55 on the same side of the pixel elements, requiring a bezel (not shown) to cover the row drivers 65 and the column drivers 75.

Various embodiments discussed herein provide systems, devices and methods that include copper interconnects formed on a glass, ceramic, or glass-ceramic substrate. Some such embodiments result in copper interconnects that are lower in resistivity compared with copper interconnects of similar shape and size formed using alternative processes, and/or allow for thinner more functional interconnects. Based upon the disclosure provided herein, one of ordinary skill in the art will recognize a variety of other advantages that may be achieved through use of the processes and devices of the disclosed embodiments.

Various embodiments provide methods for forming a metal interconnect on a substrate. Such methods include: roughening a surface of a substrate to yield a roughened surface, forming a copper alloy layer over the roughened surface; forming a copper layer disposed above the copper alloy layer to yield an interim display device; and annealing the interim display device. The phrase “copper alloy” is used in its broadest sense to mean any copper containing metal. Thus, a copper alloy may be pure copper, or a combination of copper and one or more other metals. The aforementioned roughening increases an exposed surface area when compared to an exposed surface area on a planar surface of the same dimension. The copper alloy layer includes copper and at least one other metal selected from: manganese, nickel, titanium, aluminum, zinc, magnesium, calcium, or tungsten. Annealing the interim display results in a subset of the other metal combining with the glass of the substrate to yield an interfacial layer between the substrate and the copper alloy layer.

In some instances of the aforementioned embodiments, the combination of glass and ceramic is: just glass, or a portion of glass and a portion of ceramic. In various instances of the aforementioned embodiments, the copper layer is a substantially pure copper layer. In some cases, the substantially pure copper layer exhibits a purity of greater than ninety-nine and one half percent (99.5%) copper by mol percent when measured within a band centered around a mid-point between a top surface of the layer of substantially pure metal and a top surface of the interfacial layer, and extending from the mid-point plus and minus twenty percent of the distance between the top surface of the layer of substantially pure metal and the top surface of the interfacial layer.

In various instances of the aforementioned embodiments, the other metal is manganese, and the copper alloy layer is a manganese-copper alloy layer. In some such instances, the concentration of manganese in the manganese-copper alloy layer is less than five (5) percent measured as a mol percent. In other such instances, the concentration of manganese in the manganese-copper alloy layer is less than two (2) percent measured as a mol percent. In yet other such instances, the concentration of manganese in the manganese-copper alloy layer is less one half (0.5) percent measured as a mol percent. In various such instances, the interfacial layer includes manganese-silicon-oxide (Mn SiOₓ). In one or more such instances, forming the copper layer disposed over the copper alloy layer is done in situ to avoid oxidation of the copper alloy layer. In some such instances, the method further includes oxidizing an exposed surface of the copper alloy layer prior to forming the copper layer. Annealing the interim display device yields the interfacial layer including manganese-silicon-oxide adjacent the surface of the substrate, and a layer including manganese-oxide between the interfacial layer and the copper layer.

In some instances of the aforementioned embodiments, the annealing includes exposing the interim display device to a temperature greater than two hundred eighty degrees Celsius for a period greater than one thousand seconds. In various such instances, the annealing includes exposing the interim display device to a temperature greater than three hundred twenty degrees Celsius for a period greater than one thousand seconds. In various instances of the aforementioned embodiments, roughening the surface of the substrate includes leaching the surface of the substrate. In other instances of the aforementioned embodiments, roughening the surface of the substrate includes etching the surface of the substrate.

Other embodiments provide display tiles including: a substrate formed of a combination of glass and ceramic; a metal alloy layer disposed above a surface of the substrate; and an interfacial layer of manganese-silicon-oxide (MnSiOₓ) disposed between the substrate and the metal alloy layer. In some instances of the aforementioned embodiments, the combination of glass and ceramic may be just glass, or a portion of glass and a portion of ceramic. In some instances of the aforementioned embodiments, the metal alloy layer is a substantially pure copper layer. In some such instances, the substantially pure copper layer exhibits a purity of greater than ninety-nine percent (99%) copper by mol percent when measured within a band centered around a mid-point between a top surface of the layer of substantially pure metal and a top surface of the interfacial layer, and extending from the mid-point plus and minus twenty percent of the distance between the top surface of the layer of substantially pure metal and the top surface of the interfacial layer. In various such instances, the display tile further includes manganese-oxide sandwiched between the substantially pure copper layer and the interfacial layer. In various instances of the aforementioned embodiments, a thickness of the metal alloy layer is at least three (3) times larger than a thickness of the interfacial layer. In some instances of the aforementioned embodiments, the surface of the substrate exhibits openings extending below the surface of the substrate, and wherein material of the interfacial layer extends at least partially into the openings.

Yet other embodiments provide other methods for forming a metal interconnect on a substrate. Such other methods include: forming a manganese-copper layer over a surface of a substrate that is formed of a combination of glass and ceramic; exposing a surface of the manganese-copper layer to an oxidizing environment to form an oxidized layer; forming a copper layer disposed over the oxidized layer to yield an interim display device; and annealing the interim display device to yield: an interfacial layer including manganese-silicon-oxide adjacent the surface of the substrate, and a layer including manganese-oxide between the interfacial layer and the copper layer.

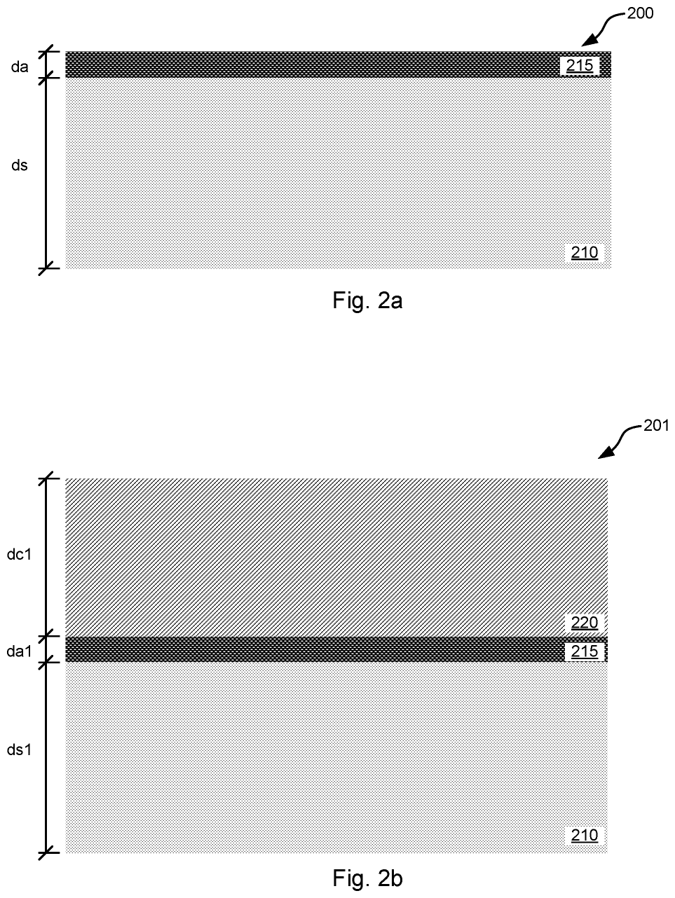

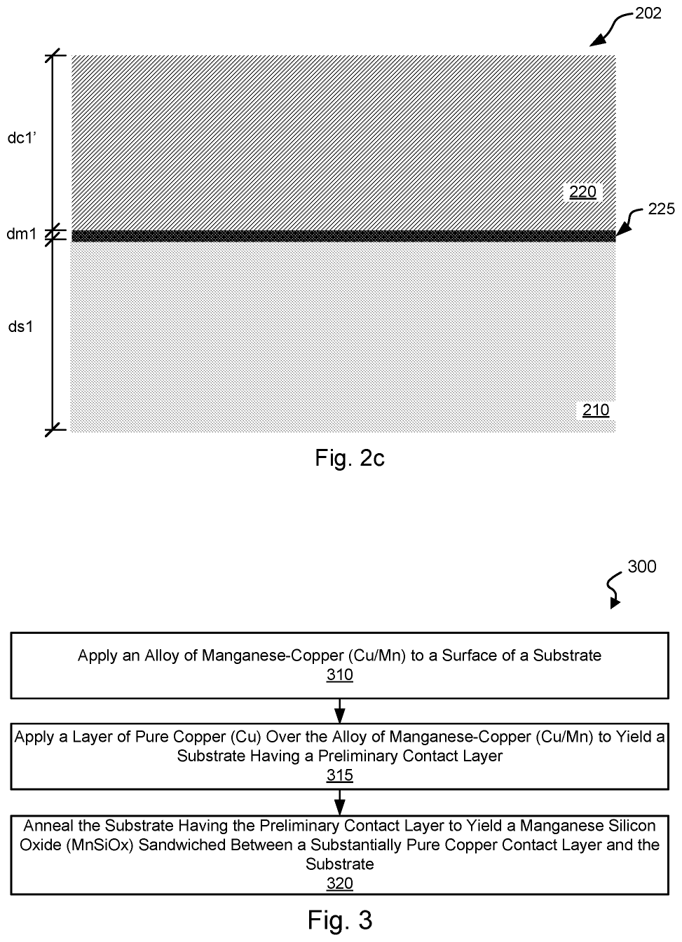

Turning to FIGS. 2a-2c, show interim display devices 200-202 after application of respective processes for forming copper interconnects on a glass or glass-ceramic display substrate in accordance with some embodiments. Considering FIG. 2a, an interim display device 200 includes a metal alloy layer 215 formed on to a surface of a substrate 210. In some embodiments, metal alloy layer 215 is formed of an alloy of manganese (Mn) and copper (Cu). In some cases, the concentration of manganese in the alloy is less than ten (10) percent. In other cases, the concentration of manganese in the alloy is less than five (5) percent. In yet other cases, the concentration of manganese in the alloy is less than two (2) percent. In yet other such instances, the concentration of manganese in the manganese-copper alloy layer is less one half (0.5) percent measured as a mol percent. Percentages of the metal alloy are provided as mol percent (mol %).

In various embodiments, substrate 210 may be any glass or glass-ceramic composition having ten (10) percent or more SiOₓ. In some embodiments, substrate 210 may be any glass or glass-ceramic composition having thirty (30) percent or more SiOₓ. In one or more embodiments, the substrate may be any glass-ceramic composition having between fifty-one (51) percent and ninety (90) percent of SiOₓ and between forty-nine (49) percent and ten (10) percent of ROₓ. The percentages of the aforementioned substrate compositions are provided as mol percent (mol %) measured within a band extending +/− twenty percent of ds1 from a centerline of substrate 210. In various embodiments, a thickness ds1 of substrate 210 is greater than ten micrometers. In some embodiments, substrate 210 is a Corning® Eagle XG® Slim Glass substrate having a thickness ds1 of between one quarter millimeter and one half millimeter. Based upon the disclosure provided herein, one of ordinary skill in the art will recognize a variety of glass or glass-ceramic substrates and substrate thicknesses that may be used in relation to different embodiments.

In some embodiments, a thickness da1 of metal alloy layer 215 is less than one hundred, fifty (150) nanometers. In various embodiments, a thickness da1 of metal alloy layer 215 is less than one hundred (100) nanometers. In some embodiments, a thickness da1 of metal alloy layer 215 is less than fifty (50) nanometers. In various embodiments, thickness da1 of metal alloy layer 215 is less than thirty (30) nanometers. In one or more embodiments, thickness da1 of metal alloy layer 215 is less than twenty (20) nanometers. In some embodiments, thickness da1 of metal alloy layer 215 is between eight (8) and thirteen (13) nanometers. Formation of metal alloy layer 215 on substrate 210 may be done using any process for forming an alloy layer of less than fifty nanometers in thickness on a substrate. Such a process may include, but is not limited to, in situ chemical vapor deposition which avoids oxidation of metal alloy layer 215.

Turning to FIG. 2b, an interim display device 201 includes a material layer 220 formed on metal alloy layer 215 of interim display device 200. In some embodiments, material layer 220 is substantially pure copper. Material layer 220 exhibits a thickness dc1 which is larger than thickness da1 . In some embodiments, thickness dc1 of material layer 220 is greater than forty (40) times that of thickness da1 of metal alloy layer 215. In some embodiments, thickness dc1 of material layer 220 is greater than twenty (20) times that of thickness da1 of metal alloy layer 215. In various embodiments, thickness dc1 of material layer 220 is greater than five (5) times that of thickness da1 of metal alloy layer 215. In some embodiments, thickness dc1 of material layer 220 is greater than three (3) times that of thickness da1 of metal alloy layer 215. In one or more embodiments, thickness dc1 of material layer 220 is greater than two (2) times that of thickness da1 of metal alloy layer 215. Formation of material layer 220 on metal alloy layer 215 may be done using any process for forming a metal layer on an alloy layer. Such a process may include, but is not limited to, sputtering or chemical vapor deposition.

Turning to FIG. 2c, an interim display device 202 is formed by annealing interim display device 201. In some embodiments, the anneal is performed by exposing interim display device 201 to a temperature of greater than two hundred, eighty (200) degrees Celsius for more than one thousand (1000) seconds. In various embodiments, the anneal is performed by exposing interim display device 201 to a temperature of approximately three hundred (300) degrees Celsius for more than one thousand, five hundred (1500) seconds. In some embodiments, the anneal is performed by exposing interim display device 201 to a temperature of approximately three hundred, fifty (350) degrees Celsius for more than one thousand, five hundred (1500) seconds. During the anneal, one metal in the alloy of metal alloy layer 215 diffuses toward the surface of substrate 210 to form a thin interfacial layer 225 between substrate 210 and material layer 220, and leaving the other metal(s) in the alloy of metal alloy layer 215. Interfacial layer 225 exhibits a thickness dm1 that is a function of: thickness da1, the percentage of the out diffusing metal in the alloy of metal alloy layer 215, and the percentage of out diffusion achieved during the anneal. As used herein, the phrases “anneal” or “annealing” are used in their broadest sense to mean any process of exposing a structure to an elevated heat for a period of time. Thus, annealing may be done, for example, by exposing an interim display device to an increased temperature after forming a material layer at a low temperature. As another example, annealing of an interim display device may be done by forming a material layer of the interim display device using elevated temperature deposition. Based upon the disclosure provided herein, one of ordinary skill in the art will recognize a variety of annealing approaches that may be used in relation to different embodiments.

Thus, in an embodiment where substrate 210 is an SiOₓ based substrate, metal alloy layer 215 is formed of a manganese-copper alloy, and material layer 220 is formed of substantially pure copper, the anneal results in diffusing the manganese of metal alloy layer 215 toward the surface of substrate 210 to form a thin layer of MnSiₓO_{y} (i.e., the metal-based oxide layer). Diffusing the manganese out of metal alloy layer 215 leaves an alloy containing a substantially reduced amount of manganese relative to copper (e.g., substantially pure copper) that becomes part of material layer 220. This results in the thickness of material layer 220 growing from the original thickness dc1 to a post anneal thickness dc1′. Similar to the thickness of dm1, the increase from thickness dc1 to dc1′ is a function of thickness da1, the percentage of manganese in the alloy of metal alloy layer 215, and the percentage of out diffusion of manganese achieved during the anneal. Interfacial layer 225 (in this case, the thin layer of MnSiₓO_{y}) serves as an adhesion layer between the substantially pure copper in material layer 220 and the surface of substrate 210. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer. Further, the aforementioned lower resistivity was achievable with a low concentration of manganese and a metal alloy layer 215 of less than one hundred (100) nanometers.

It has been found through experimentation that resistivity decreases as a function of the thickness of metal alloy layer 215. For example, for a concentration of manganese of less than two (2) percent by mol % of the manganese-copper alloy, a material layer 220 with a thickness dc1 of five hundred (500) nanometers, and a metal alloy layer 215 with a thickness da1 of one hundred, fifty (150) nanometers, a resistivity of between 2.6 and 2.8 microOhms per centimeter (μΩcm) was achieved depending upon whether an anneal was applied, the temperature and duration of the anneal with the lowest resistivity occurring for anneals at three hundred (300) degrees Celsius for greater than approximately one thousand five hundred (1500) seconds. For a concentration of manganese of less than one half (0.5) percent by mol % of the manganese-copper alloy, a material layer 220 with a thickness dc1 of five hundred (500) nanometers, and a metal alloy layer 215 with a thickness da1 of one hundred (100) nanometers, a resistivity of between 2.4 and 2.6 microOhms per centimeter (μΩcm) was achieved depending upon whether an anneal was applied, the temperature and duration of the anneal with the lowest resistivity occurring for anneals at three hundred (300) degrees Celsius for greater than approximately one thousand five hundred (1500) seconds. For a concentration of manganese of less than one half (0.5) percent by mol % of the manganese-copper alloy, a material layer 220 with a thickness dc1 of five hundred (500) nanometers, and a metal alloy layer 215 with a thickness da1 of fifty (50) nanometers, a resistivity of between 2.2 and 2.4 microOhms per centimeter (μΩcm) was achieved depending upon whether an anneal was applied, the temperature and duration of the anneal with the lowest resistivity occurring for anneals at three hundred (300) degrees Celsius for greater than approximately one thousand five hundred (1500) seconds. For a concentration of manganese of less than two (2) percent by weight of the manganese-copper alloy, a material layer 220 with a thickness dc1 of five hundred (500) nanometers, and a metal alloy layer 215 with a thickness da1 of ten (10) nanometers, a resistivity of between 2.0 and 2.3 microOhms per centimeter (μΩcm) was achieved depending upon whether an anneal was applied, the temperature and duration of the anneal with the lowest resistivity occurring for anneals at three hundred, fifty (350) degrees Celsius for greater than approximately one thousand five hundred (1500) seconds. The resistivity for the metal alloy layer 215 with a thickness da1 of ten (10) nanometers can be further reduced to less than 1.9 microOhms per centimeter (μΩcm) where a post annealing process of a gas annealing (four (4) percent H₂) is performed.

Turning to FIG. 3, a flow diagram 300 shows a method for forming copper interconnects on a glass or glass-ceramic display substrate in accordance with various embodiments. Following flow diagram 300, an alloy of manganese and copper is applied to a surface of a substrate (block 310). In some cases, the surface of the substrate has been placed in an oxidizing environment prior to applying the alloy of manganese (Mn) and copper (Cu). In some cases, the concentration of manganese in the alloy is less than two (2) percent. Again, percentages of the metal alloy are provided as mol percent (mol %). In some embodiments, the layer of the alloy of manganese and copper is approximately ten (10) nanometers thick. Applying the alloy of manganese and copper may be done using any process for forming an alloy layer of approximately ten (10) nanometers in thickness on a substrate. Such a process may include, but is not limited to, in situ chemical vapor deposition which avoids oxidation of metal alloy layer 215.

A layer of substantially pure copper (Cu) is applied over the alloy of manganese and copper to yield a substrate having a preliminary contact layer (block 315). Such a preliminary contact layer is similar to material layer 220 of FIG. 2b. In some cases, the layer of pure copper exhibits a thickness of approximately five hundred nanometers. Applying the substantially pure copper layer may be done using any process for forming a copper layer of approximately five hundred (500) nanometers in thickness over a manganese-copper alloy. Such a process may include, but is not limited to, sputtering or chemical vapor deposition.

The substrate having the preliminary contact layer is annealed to yield a manganese-silicon-oxide (MnSiₓO_{y}) disposed between a substantially pure copper contact layer and the substrate (block 320). In some cases, the anneal is performed at a temperature between three hundred (300) degrees Celsius and three hundred, fifty (350) degrees Celsius for more than one thousand five hundred (1500) seconds. During the anneal, the manganese diffuses out of the manganese-copper alloy toward the substrate, and the copper from the manganese-copper alloy remains and becomes part of a substantially pure copper layer similar to that shown in FIG. 2c above. The interfacial layer of MnSiₓO_{y} serves as an adhesion layer between the substantially pure copper in material layer the surface of the substrate. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer.

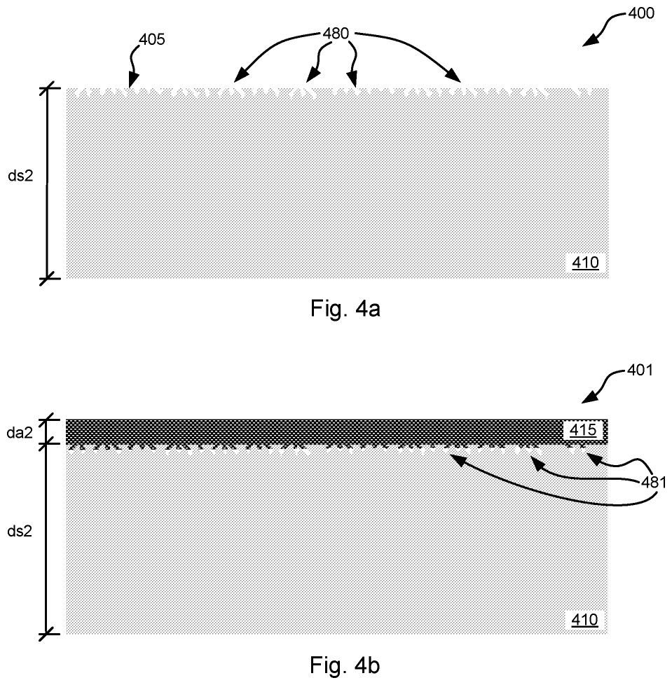

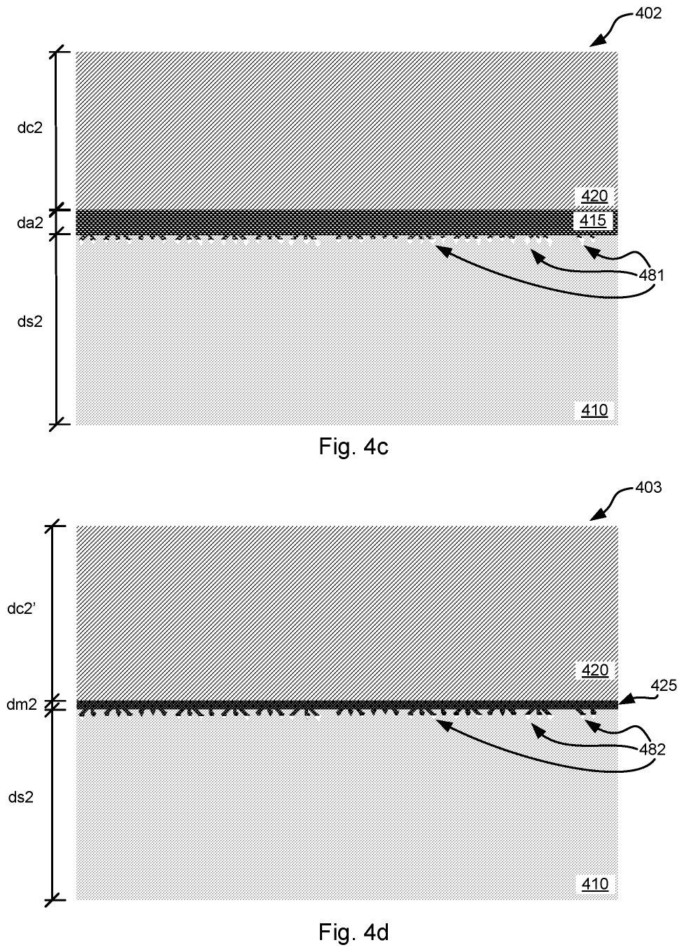

Turning to FIGS. 4a-4d, show interim display devices 400-403 after application of respective processes for forming copper interconnects on a glass or glass-ceramic display substrate including expanding oxygen area on the surface of the substrate in accordance with some embodiments. Considering FIG. 4a, an interim display device 400 includes a substrate 410 having a thickness ds2. As shown, small openings 480 are formed that extend below a surface 405 of substrate 410. These small openings may be formed by any chemical or mechanical process known in the art. In some embodiments, the small openings 480 are nanoporous openings formed by leaching surface 405. In other embodiments, the small openings 405 are etched openings formed by etching surface 405. Based upon the disclosure provided herein, one of ordinary skill in the art will recognize a variety of roughing processes that may be applied to surface 405 to increase the area of surface 405. In various embodiments, a thickness ds2 of substrate 410 is greater than ten micrometers. In some embodiments, substrate 410 is a Corning® Eagle XG® Slim Glass substrate having a thickness ds2 of between one quarter millimeter and one half millimeter. Based upon the disclosure provided herein, one of ordinary skill in the art will recognize a variety of glass or glass-ceramic substrates and substrate thicknesses that may be used in relation to different embodiments.

In various embodiments, substrate 410 may be any glass or glass-ceramic composition having ten (10) percent or more SiOₓ. In some embodiments, substrate 410 may be any glass or glass-ceramic composition having thirty (30) percent or more SiOₓ. In one or more embodiments, substrate 410 may be any glass-ceramic composition having between fifty-one (51) percent and ninety (90) percent of SiOₓ and between forty-nine (49) percent and ten (10) percent of ROₓ. The percentages of the aforementioned substrate compositions are provided as mol percent (mol %) on an oxide basis measured within a band extending +/− twenty percent of ds2 from a centerline of substrate 410. In some embodiments, to enhance the structural integrity of the framework of majority-component material remaining after leaching minority components ROₓ, while also having an amount of ROₓ sufficient to generate a robust nanoporous network when leached, the original bulk SiO₂ content is 55% to 80% and the minority components ROₓ comprise 20% to 45%, or the original bulk SiO₂ content is 64% to 71%, and the minority components ROₓ comprise 29% to 36% of the bulk composition. In some embodiments, Al₂O₃ is one of the minority components ROₓ , and Al₂O₃ is the component having the highest mole percent (mol %) on an oxide basis after SiO₂.

In some embodiments, minority components ROₓ are selected from: Al₂O₃, B₂O₃, MgO, CaO, SrO, BaO, and combinations thereof. The leachants described herein remove each of these components at a rate significantly higher than the rate at which they remove SiO₂. In some embodiments, +/− twenty percent of ds2 from a centerline of substrate 410, substrate 410 has a composition, in mole percent on an oxide basis:

SiO₂: 64.0-71.0

Al₂O₃: 9.0-12.0

B₂O₃: 7.0-12.0

MgO: 1.0-3.0

CaO: 6.0-11.5

SrO: 0-2.0

BaO: 0-0.1

(herein after “Composition 1”)
For the compositions described above, the etchants described herein remove SiO₂ at a rate higher than that at which they remove the other components. And, the leachants described herein remove each of the ROₓ components (components other than SiO₂) at about the same rate, which is significantly higher than the rate at which the leachants remove SiO₂. The amount of SiO₂ remaining after the other components have been leached is sufficient to form a robust framework. And, the amount of ROₓ components is sufficient to form a nanoporous layer when leached.

As used herein, the phrases “leach” or “leaching” are used in their broadest sense to mean any process that selectively removes minority components ROₓ from substrate 410 preferentially to removal of SiO₂. Leaching occurs when a leaching agent, such as an acid, removes the minority components ROₓ at a faster rate than SiO₂. As a result, the percentage of ROₓ removed, compared to the amount of SiO₂, is greater than would be expected if all components were removed at a rate proportionate to the amount of component in the composition.

As used herein, a “leached layer” refers to a layer in which the ROₓ concentration is fifty percent (50%) or less than the ROₓ concentration of the composition due to preferential removal with a leaching agent of the ROₓ component from the leached layer compared to removal of SiO2. Due to the way it is formed, where a leached layer has unique structural characteristics when compared, for example, to a layer having the same composition as the leached layer, but formed by a different method. Compared to the non-leached composition, ROₓ has been removed from the leached layer. The SiO₂ and reduced amount ROₓ components that remain retain the microstructure from the non-leached composition, with spaces or pores where the leached ROₓ was removed. For the compositions described herein, such as Composition 1, leaching generally results in a leached layer having a nanoporous structure with a re-entrant geometry.

Directly measuring the ROₓ concentration to see whether it is 50% or less than the ROₓ concentration of the non-leached composition by SIMS analysis involves measuring each ROₓ component by SIMS. Unless otherwise specified, this is how ROₓ concentration is measured. As used herein, a “re-entrant geometry” refers to a surface geometry (e.g. a geometry of surface 405) where there is at least one line perpendicular to a major surface that crosses the surface of the material more than once. A “major surface” of a material is the surface on a macroscopic scale—the surface defines by a plane that rests on, but does not intersect, the material. For a re-entrant geometry, there is at least one line that enters the material, exits the material (into an open nanopore, for example), and re-enters the material. Where the re-entrant geometry is filled, for example, with a manganese-copper alloy, even if the manganese-copper alloy is not bonded to the material, mechanical interlocking prevents pulling the manganese-copper alloy straight out without deforming the manganese-copper alloy or surface 405. A rough surface may or may not be re-entrant. A nanoporous surface will almost always be re-entrant, although the unlikely case of cylindrical pores, not interconnecting and all aligned perpendicular to the surface, is not re-entrant.

As used herein, the phrases “etch” or “etching” are used in their broadest sense to mean any process that selectively removing a majority component A of the glass substrate preferentially to the removal of minority components B. The etchants used to preferentially remove the majority component A can and often do also remove minority components B, but at a rate slower than they remove majority component A. Minority components B are generally removed along with the majority component A during etching, as minority components B are quite exposed to etchant and have limited structural integrity once majority component A is removed. In some embodiments not illustrated herein, all surfaces of substrate 410 are exposed to the etchant. But, in other embodiments, selected surfaces (e.g., surface 405 of substrate 410) of substrate 410 may be protected from exposure to etchant, for example by photoresist or other protective layer, in which case the selected surfaces would not be etched.

A glass surface that has been etched has distinctive structural characteristics, and one of skill in the art can tell from inspecting a glass surface whether that surface has been etched. Etching often changes the surface roughness of the glass. So, if one knows the source of the glass and the roughness of that source, a measurement of surface roughness can be used to determine whether the glass has been etched. In addition, etching generally results in differential removal of different materials in the glass. This differential removal can be detected by techniques such as electron probe microanalysis (EPMA). Moreover, in the case of previously leached surfaces, etching may remove a portion of the leached layer, as described herein, which is another structural difference between etched and un-etched layers.

Turning to FIG. 4b, an interim display device 401 includes a metal alloy layer 415 formed on surface 405 that at least partially enters into small openings 480 which are shown as partially filled openings 481. In some embodiments, metal alloy layer 415 is formed of an alloy of manganese (Mn) and copper (Cu). In some cases, the concentration of manganese in the alloy is less than ten (10) percent by mole percent (mol %). In other cases, the concentration of manganese in the alloy is less than five (5) percent by mole percent (mol %). In yet other cases, the concentration of manganese in the alloy is less than two (2) percent by mole percent (mol %).

In some embodiments, a thickness da2 of metal alloy layer 415 is less than one hundred, fifty (150) nanometers. In various embodiments, a thickness da2 of metal alloy layer 415 is less than one hundred (100) nanometers. In some embodiments, a thickness da2 of metal alloy layer 415 is less than fifty (50) nanometers. In various embodiments, thickness da2 of metal alloy layer 415 is less than thirty (30) nanometers. In one or more embodiments, thickness da2 of metal alloy layer 415 is less than twenty (20) nanometers. In some embodiments, thickness da2 of metal alloy layer 415 is between eight (8) and thirteen (13) nanometers. Formation of metal alloy layer 415 on substrate 410 may be done using any process for forming an alloy layer of less than fifty nanometers in thickness on a substrate. Such a process may include, but is not limited to, in situ chemical vapor deposition which avoids oxidation of metal alloy layer 215.

Turning to FIG. 4c, an interim display device 402 includes a material layer 420 formed on metal alloy layer 415 of interim display device 401. In some embodiments, material layer 420 is substantially pure copper. Material layer 420 exhibits a thickness dc2 which is larger than thickness da2. In some embodiments, thickness dc2 of material layer 420 is greater than forty (40) times that of thickness da2 of metal alloy layer 415. In some embodiments, thickness dc2 of material layer 420 is greater than twenty (20) times that of thickness da2 of metal alloy layer 415. In various embodiments, thickness dc2 of material layer 420 is greater than five (5) times that of thickness da2 of metal alloy layer 415. In some embodiments, thickness dc2 of material layer 420 is greater than three (3) times that of thickness da2 of metal alloy layer 415. In one or more embodiments, thickness dc2 of material layer 420 is greater than two (2) times that of thickness da2 of metal alloy layer 415. Formation of material layer 420 on metal alloy layer 415 may be done using any process for forming a metal layer on an alloy layer. Such a process may include, but is not limited to, sputtering or chemical vapor deposition.

Turning to FIG. 4d, an interim display device 403 is formed by annealing interim display device 402. In some embodiments, the anneal is performed by exposing interim display device 402 to a temperature of greater than two hundred, eighty (200) degrees Celsius for more than one thousand (1000) seconds. In various embodiments, the anneal is performed by exposing interim display device 402 to a temperature of approximately three hundred (300) degrees Celsius for more than one thousand, five hundred (1500) seconds. In some embodiments, the anneal is performed by exposing interim display device 402 to a temperature of approximately three hundred, fifty (350) degrees Celsius for more than one thousand, five hundred (1500) seconds. During the anneal, one metal in the alloy of metal alloy layer 415 diffuses toward the surface of substrate 410 to form a thin interfacial layer 425 between substrate 410 and material layer 420, and leaving the other metal(s) in the alloy of metal alloy layer 415. Interfacial layer 425 exhibits a thickness dm2 that is a function of: thickness da2, the percentage of the out diffusing metal in the alloy of metal alloy layer 415, and the percentage of out diffusion achieved during the anneal. As shown, during the anneal, some of the manganese may diffuse further into small openings 480 which are shown as partially filled openings 482.

Thus, in an embodiment where substrate 410 is an SiOₓ based substrate, metal alloy layer 415 is formed of a manganese-copper alloy, and material layer 420 is formed of substantially pure copper, the anneal results in diffusing the manganese of metal alloy layer 415 diffuses toward the surface of substrate 410 to form a thin layer of MnSiₓO_{y} (i.e., the metal-based oxide layer). Diffusing the manganese out of metal alloy layer 415 leaves copper that becomes part of material layer 420. This results in the thickness of material layer 420 growing from the original thickness dc2 to a post anneal thickness dc2′. Similar to the thickness of dm2, the increase from thickness dc2 to dc2′ is a function of thickness da2, the percentage of manganese in the alloy of metal alloy layer 415, and the percentage of out diffusion of manganese achieved during the anneal. Interfacial layer 425 (in this case, the thin layer of MnSiₓO_{y}) serves as an adhesion layer between the substantially pure copper in material layer 420 and the surface of substrate 410. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer. Further, the aforementioned lower resistivity was achievable with a low concentration of manganese and a metal alloy layer 415 of less than one hundred (100) nanometers.

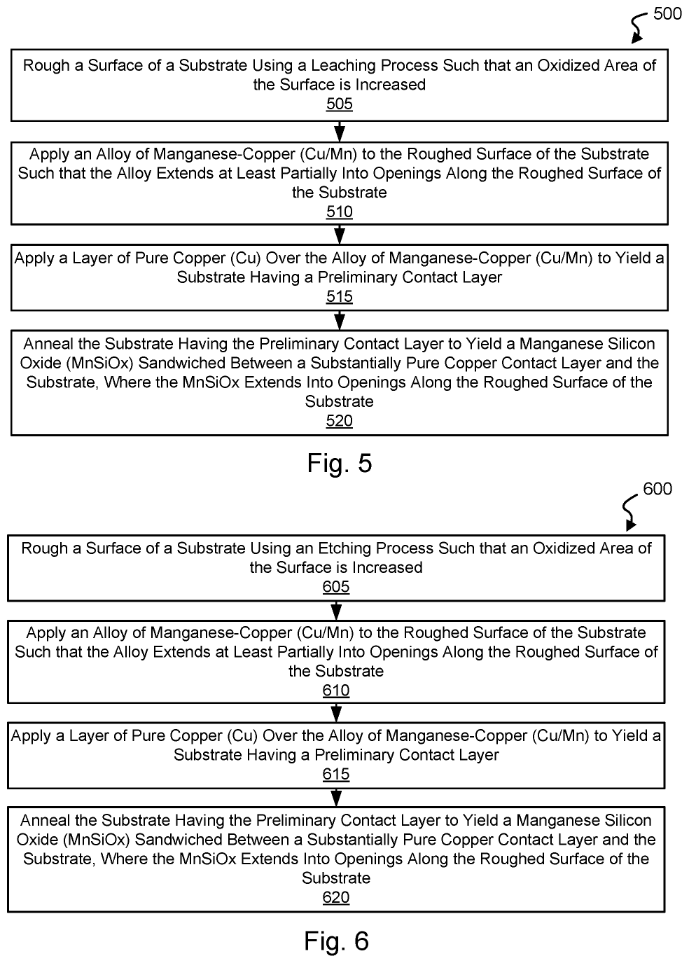

Turning to FIG. 5, a flow diagram 500 shows a method for forming copper interconnects on a glass or glass-ceramic display substrate including expanding oxygen area on the surface of the substrate using a leaching process in accordance with various embodiments. Following flow diagram 500, a leaching process is applied to a surface of a substrate to rough the surface, and thus increase an oxidized area of the surface (block 505). This includes applying a leachant or leachants to a surface of the substrate such that small openings are formed in the surface of the substrate. Depending upon the desired composition of the substrate, one of ordinary skill in the art will understand what leachant or leachants are appropriate and the amount of exposure time required to open small holes in the surface of a substrate. In some embodiments, opening the small holes increases an exposed surface area of the substrate by more than 1.2 times over a non-roughed surface. In various embodiments, opening the small holes increases an exposed surface area of the substrate by more than 1.8 times over a non-roughed surface.

An alloy of manganese and copper is applied to a surface of a substrate (block 510). In some cases, the surface of the substrate has been placed in an oxidizing environment prior to applying the alloy of manganese (Mn) and copper (Cu). In some cases, the concentration of manganese in the alloy is less than two (2) percent. Again, percentages of the metal alloy are provided as mol percent (mol %). In some embodiments, the layer of the alloy of manganese and copper is approximately ten (10) nanometers thick. Applying the alloy of manganese and copper may be done using any process for forming an alloy layer of approximately ten (10) nanometers in thickness on a substrate. Such a process may include, but is not limited to, chemical vapor deposition.

A layer of substantially pure copper (Cu) is applied over the alloy of manganese and copper to yield a substrate having a preliminary contact layer (block 515). Such a preliminary contact layer is similar to material layer 220 of FIG. 2b. In some cases, the layer of pure copper exhibits a thickness of approximately five hundred nanometers. Applying the substantially pure copper layer may be done using any process for forming a copper layer of approximately five hundred (500) nanometers in thickness over a manganese-copper alloy. Such a process may include, but is not limited to, sputtering or chemical vapor deposition.

The substrate having the preliminary contact layer is annealed to yield a manganese-silicon-oxide (MnSiₓO_{y}) sandwiched between a substantially pure copper contact layer and the substrate (block 520). In some cases, the anneal is performed at a temperature between three hundred (300) degrees Celsius and three hundred, fifty (350) degrees Celsius for more than one thousand five hundred (1500) seconds. During the anneal, the manganese diffuses out of the manganese-copper alloy toward the substrate, and the copper from the manganese-copper alloy remains and becomes part of a substantially pure copper layer similar to that shown in FIG. 2c above. The interfacial layer of MnSiₓO_{y} serves as an adhesion layer between the substantially pure copper in material layer the surface of the substrate. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer.

FIG. 6 is a flow diagram showing another method for forming copper interconnects on a glass or glass-ceramic display substrate including expanding oxygen area on the surface of the substrate using an etching process in accordance with various embodiments. Following flow diagram 600, and etching process is applied to a surface of a substrate to rough the surface, and thus increase an oxidized area of the surface (block 605). This includes applying an etchant or etchants to a surface of the substrate such that small openings are formed in the surface of the substrate. Depending upon the desired composition of the substrate, one of ordinary skill in the art will understand what etchant or etchants are appropriate and the amount of exposure time required to open small holes in the surface of a substrate. In some embodiments, opening the small holes increases an exposed surface area of the substrate by more than 1.2 times over a non-roughed surface. In various embodiments, opening the small holes increases an exposed surface area of the substrate by more than 1.8 times over a non-roughed surface.

An alloy of manganese and copper is applied to a surface of a substrate (block 610). In some cases, the surface of the substrate has been placed in an oxidizing environment prior to applying the alloy of manganese (Mn) and copper (Cu). In some cases, the concentration of manganese in the alloy is less than two (2) percent. Again, percentages of the metal alloy are provided as mol percent (mol %). In some embodiments, the layer of the alloy of manganese and copper is approximately ten (10) nanometers thick. Applying the alloy of manganese and copper may be done using any process for forming an alloy layer of approximately ten (10) nanometers in thickness on a substrate. Such a process may include, but is not limited to, chemical vapor deposition.

A layer of substantially pure copper (Cu) is applied over the alloy of manganese and copper to yield a substrate having a preliminary contact layer (block 615). Such a preliminary contact layer is similar to material layer 220 of FIG. 2b. In some cases, the layer of pure copper exhibits a thickness of approximately five hundred nanometers. Applying the substantially pure copper layer may be done using any process for forming a copper layer of approximately five hundred (500) nanometers in thickness over a manganese-copper alloy. Such a process may include, but is not limited to, sputtering or chemical vapor deposition.

The substrate having the preliminary contact layer is annealed to yield a manganese-silicon-oxide (MnSiₓO_{y}) sandwiched between a substantially pure copper contact layer and the substrate (block 620). In some cases, the anneal is performed at a temperature between three hundred (300) degrees Celsius and three hundred, fifty (350) degrees Celsius for more than one thousand five hundred (1500) seconds. During the anneal, the manganese diffuses out of the manganese-copper alloy toward the substrate, and the copper from the manganese-copper alloy remains and becomes part of a substantially pure copper layer similar to that shown in FIG. 2c above. The interfacial layer of MnSiₓO_{y} serves as an adhesion layer between the substantially pure copper in material layer the surface of the substrate. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer.

While not shown in either flow diagram 500 of FIG. 5 or flow diagram 600 of FIG. 6, roughening surface 405 may be done using a combination of leaching and etching. This may include, for example, applying a leaching process to surface 405 of substrate 410 followed by applying an etching process to the same surface. Alternatively, this may include, for example, applying an etching process to surface 405 of substrate 410 followed by applying a leaching process to the same surface.

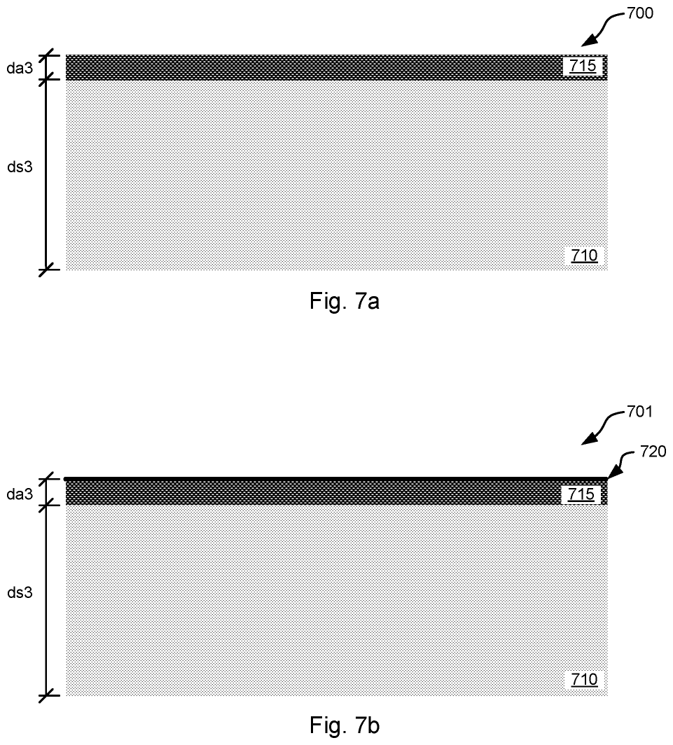

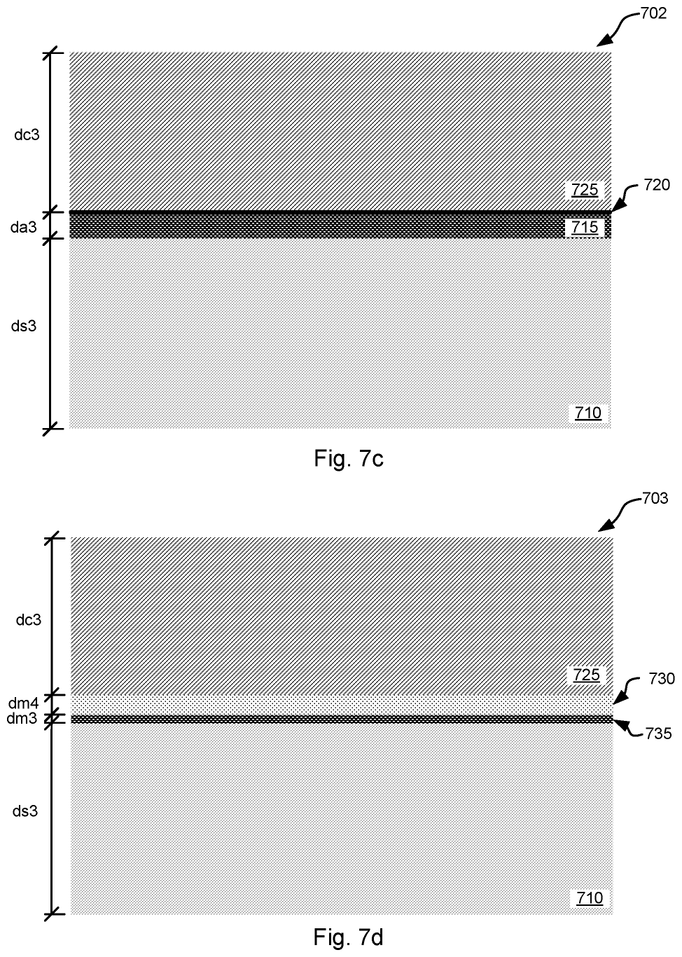

Turning to FIGS. 7a-7d, show interim display devices 700-703 after application of respective processes for forming copper interconnects on a glass or glass-ceramic display substrate including a stop layer 720 disposed over the surface of the substrate in accordance with some embodiments. Considering FIG. 7a, an interim display device 700 includes a metal alloy layer 715 formed on to a surface of a substrate 710. In some embodiments, metal alloy layer 715 is formed of an alloy of manganese (Mn) and copper (Cu). In some cases, the concentration of manganese in the alloy is less than ten (10) percent. In other cases, the concentration of manganese in the alloy is less than five (5) percent. In yet other cases, the concentration of manganese in the alloy is less than two (2) percent. Again, percentages of the metal alloy are provided as mol percent (mol %).

In various embodiments, substrate 710 may be any glass or glass-ceramic composition having ten (10) percent or more SiOₓ. In some embodiments, substrate 710 may be any glass or glass-ceramic composition having thirty (30) percent or more SiOₓ. In one or more embodiments, the substrate may be any glass-ceramic composition having between fifty-one (51) percent and ninety (90) percent of SiOₓ and between forty-nine (49) percent and ten (10) percent of ROₓ. The percentages of the aforementioned substrate compositions are provided as mol percent (mol %) measured within a band extending +/− twenty percent of ds3 from a centerline of substrate 710. In various embodiments, a thickness ds3 of substrate 710 is greater than ten micrometers. In some embodiments, substrate 710 is a Corning® Eagle XG® Slim Glass substrate having a thickness ds3 of between one quarter millimeter and one half millimeter. Based upon the disclosure provided herein, one of ordinary skill in the art will recognize a variety of glass or glass-ceramic substrates and substrate thicknesses that may be used in relation to different embodiments.

In some embodiments, a thickness da3 of metal alloy layer 715 is less than one hundred, fifty (150) nanometers. In various embodiments, a thickness da3 of metal alloy layer 715 is less than one hundred (100) nanometers. In some embodiments, a thickness da3 of metal alloy layer 715 is less than fifty (50) nanometers. In various embodiments, thickness da3 of metal alloy layer 715 is less than thirty (30) nanometers. In one or more embodiments, thickness da3 of metal alloy layer 715 is less than twenty (20) nanometers. In some embodiments, thickness da3 of metal alloy layer 715 is between eight (8) and thirteen (13) nanometers. Formation of metal alloy layer 715 on substrate 710 may be done using any process for forming an alloy layer of less than fifty nanometers in thickness on a substrate. Such a process may include, but is not limited to, chemical vapor deposition.

Turning to FIG. 7b, an interim display device 701 includes a stop layer 720 formed over metal alloy layer 715. Stop layer 720 is formed by promoting the oxidation of metal alloy layer 715. Where metal alloy layer 715 is an alloy of manganese and copper, stop layer 720 is a manganese-copper oxide (MnCuOx) layer. The thickness of stop layer 720 is a small percentage of the thickness of metal alloy layer 715. In some embodiments, the oxidation of metal alloy layer 715 by incurring a vacuum break that allows oxygen to engage the exposed surface of the surface of metal alloy layer 715. In some cases, interim display device 701 may be exposed to an environment of pure oxygen or just an oxygen containing environment.

Turning to FIG. 7c, an interim display device 702 includes a material layer 725 formed on stop layer 720 of interim display device 701. In some embodiments, material layer 725 is substantially pure copper. Material layer 725 exhibits a thickness dc3 which is larger than thickness da3. In some embodiments, thickness dc3 of material layer 725 is greater than forty (40) times that of thickness da3 of metal alloy layer 715. In some embodiments, thickness dc3 of material layer 725 is greater than twenty (20) times that of thickness da3 of metal alloy layer 715. In various embodiments, thickness dc3 of material layer 725 is greater than five (5) times that of thickness da3 of metal alloy layer 715. In some embodiments, thickness dc3 of material layer 725 is greater than three (3) times that of thickness da3 of metal alloy layer 715. In one or more embodiments, thickness dc3 of material layer 725 is greater than two (2) times that of thickness da3 of metal alloy layer 715. Formation of material layer 725 on metal alloy layer 715 may be done using any process for forming a metal layer on an alloy layer. Such a process may include, but is not limited to, sputtering or chemical vapor deposition.

Turning to FIG. 7d, an interim display device 703 is formed by annealing interim display device 702. In some embodiments, the anneal is performed by exposing interim display device 702 to a temperature of greater than two hundred, eighty (200) degrees Celsius for more than one thousand (1000) seconds. In various embodiments, the anneal is performed by exposing interim display device 702 to a temperature of approximately three hundred (300) degrees Celsius for more than one thousand, five hundred (1500) seconds. In some embodiments, the anneal is performed by exposing interim display device 702 to a temperature of approximately three hundred, fifty (350) degrees Celsius for more than one thousand, five hundred (1500) seconds. During the anneal, one metal in the alloy of metal alloy layer 715 diffuses toward the surface of substrate 710 to form a thin interfacial layer 735 between substrate 710 and material layer 725, and leaving the other metal(s) in the alloy of metal alloy layer 715. Interfacial layer 735 exhibits a thickness dm3 that is a function of: thickness da3, the percentage of the out diffusing metal in the alloy of metal alloy layer 715, and the percentage of out diffusion achieved during the anneal.

Thus, in an embodiment where substrate 710 is an SiOₓ based substrate, metal alloy layer 715 is formed of a manganese-copper alloy, and material layer 725 is formed of substantially pure copper, the anneal results in diffusing the manganese of metal alloy layer 715 diffuses toward the surface of substrate 710 to form a thin layer of MnSiₓO_{y} (i.e., the metal-based oxide layer). Diffusing the manganese out of metal alloy layer 715 leaves copper that becomes part of material layer 725. The oxygen in stop layer 720 reduces the ability of manganese from metal alloy layer 715 to diffuse out into material layer 725. The copper oxide (CuOx) in stop layer 720 is reduced to copper by manganese diffusion from metal alloy layer 715 toward material layer 725. This results in an intervening layer 730 including a combination of manganese-oxide (MnOx), copper (Cu), and copper-oxide (CuOx) depending upon the diffusion and recombination achieved during the anneal. In some embodiments, manganese-oxide forms the largest material concentration in intervening layer 730 when measured as an atomic percent. The thickness da3 of metal alloy layer 715 is approximately equal to a thickness dm4 of intervening layer 730 added to a thickness dm3 of interfacial layer 735. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer. Further, the aforementioned lower resistivity was achievable with a low concentration of manganese and a metal alloy layer 715 of less than one hundred (100) nanometers. Addition of the stop layer 720 results in intervening layer 730 that provides a good adhesion layer between material layer 725 and interfacial layer 735.

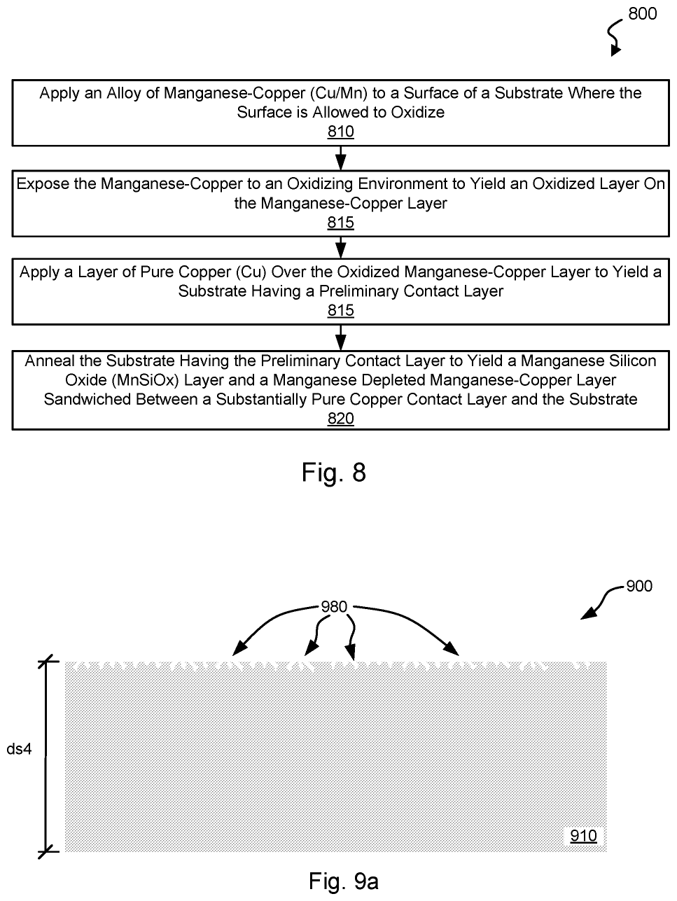

Turning to FIG. 8, a flow diagram 800 shows a method for forming copper interconnects on a glass or glass-ceramic display substrate including forming a stop layer over the surface of the substrate in accordance with one or more embodiments. Following flow diagram 800, an alloy of manganese and copper is applied to a surface of a substrate (block 810). In some cases, the surface of the substrate has been placed in an oxidizing environment prior to applying the alloy of manganese (Mn) and copper (Cu). In some cases, the concentration of manganese in the alloy is less than two (2) percent. Again, percentages of the metal alloy are provided as mol percent (mol %). In some embodiments, the layer of the alloy of manganese and copper is approximately ten (10) nanometers thick. Applying the alloy of manganese and copper may be done using any process for forming an alloy layer of approximately ten (10) nanometers in thickness on a substrate. Such a process may include, but is not limited to, chemical vapor deposition.

The manganese-copper alloy layer is exposed to an oxidizing environment to promote the formation of an oxidized layer (MnCuOx) (block 815). The oxidizing environment may be a pure oxygen environment, or just an oxygen containing environment. A layer of substantially pure copper (Cu) is applied over the oxidized layer on the manganese-copper alloy layer to yield a substrate having a preliminary contact layer (block 815). Such a preliminary contact layer is similar to material layer 725 of FIG. 7c. In some cases, the layer of pure copper exhibits a thickness of approximately five hundred nanometers. Applying the substantially pure copper layer may be done using any process for forming a copper layer of approximately five hundred (500) nanometers in thickness over a manganese-copper alloy. Such a process may include, but is not limited to, sputtering or chemical vapor deposition.

The substrate having the preliminary contact layer is annealed to yield a manganese-silicon-oxide (MnSiₓO_{y}) layer over the substrate and a manganese depleted manganese-copper layer over the manganese-silicon-oxide layer and below the pure copper layer (block 820). In some cases, the anneal is performed at a temperature between three hundred (300) degrees Celsius and three hundred, fifty (350) degrees Celsius for more than one thousand five hundred (1500) seconds. During the anneal, the manganese diffuses out of the manganese-copper alloy toward the substrate, and the copper from the manganese-copper alloy remains and becomes part of a substantially pure copper layer similar to that shown in FIG. 7d above. The interfacial layer of MnSiₓO_{y} serves as an adhesion layer between the manganese depleted manganese-copper layer and the surface of the substrate, and the manganese depleted manganese-copper layer serves as an adhesion layer between the interfacial layer and the layer of pure copper.

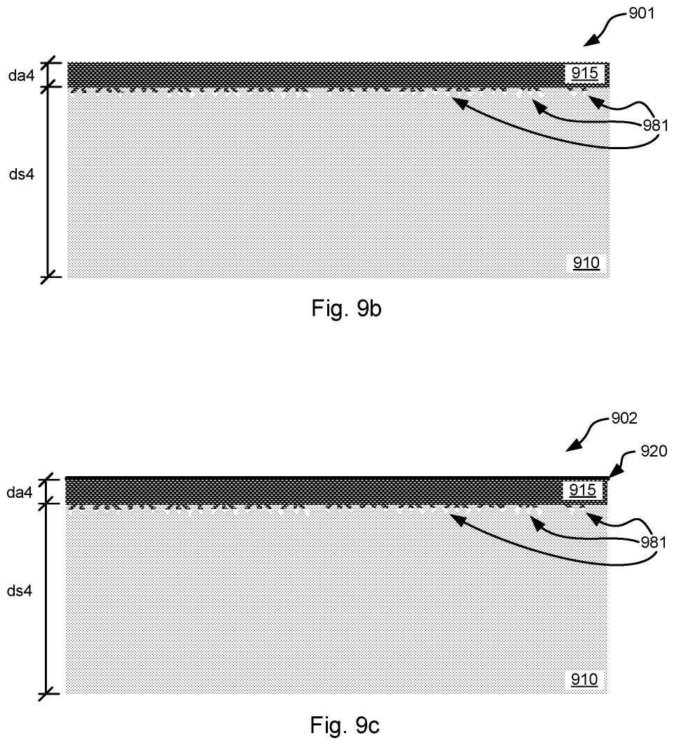

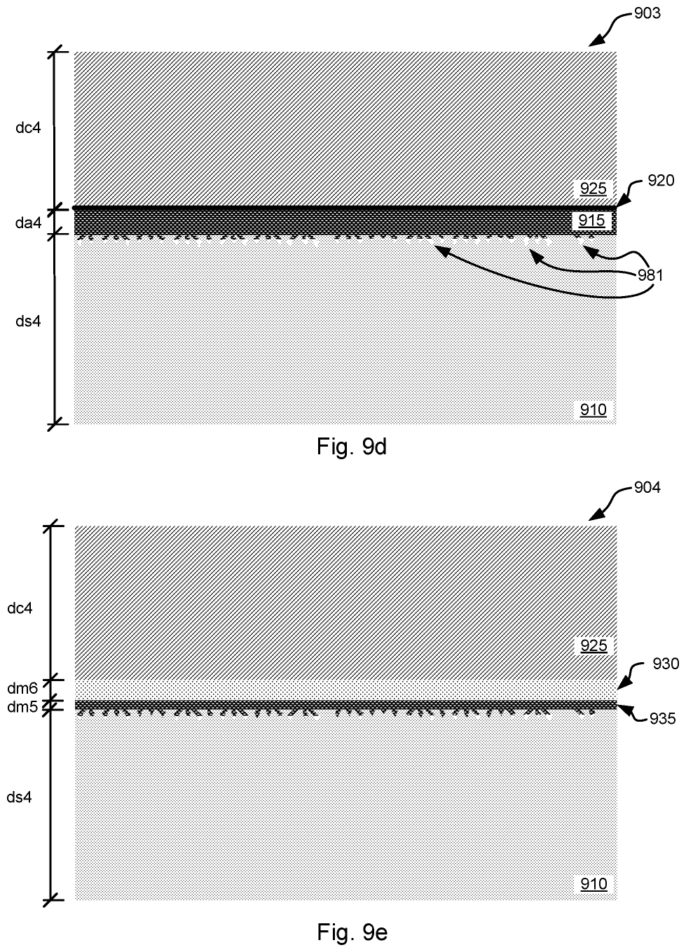

Turning to FIGS. 9a-9e, show interim display devices 900-904 after application of respective processes for forming copper interconnects on a glass or glass-ceramic display substrate including expanding oxygen area on the surface of the substrate and forming a stop layer over the surface of the substrate in accordance with some embodiments. Considering FIG. 9a, an interim display device 900 includes a substrate 910 having a thickness ds4. As shown, small openings 980 are formed that extend below a surface 905 of substrate 910. These small openings may be formed by any chemical or mechanical process known in the art. In some embodiments, the small openings 980 are nanoporous openings formed by leaching surface 905. In other embodiments, the small openings 905 are etched openings formed by etching surface 905. Based upon the disclosure provided herein, one of ordinary skill in the art will recognize a variety of roughing processes that may be applied to surface 905 to increase the area of surface 905. In various embodiments, a thickness ds4 of substrate 910 is greater than ten micrometers. In some embodiments, substrate 910 is a Corning® Eagle XG® Slim Glass substrate having a thickness ds4 of between one quarter millimeter and one half millimeter. Based upon the disclosure provided herein, one of ordinary skill in the art will recognize a variety of glass or glass-ceramic substrates and substrate thicknesses that may be used in relation to different embodiments.

In various embodiments, substrate 910 may be any glass or glass-ceramic composition having ten (10) percent or more SiOₓ. In some embodiments, substrate 910 may be any glass or glass-ceramic composition having thirty (30) percent or more SiOₓ. In one or more embodiments, substrate 910 may be any glass-ceramic composition having between fifty-one (51) percent and ninety (90) percent of SiOₓ and between forty-nine (49) percent and ten (10) percent of ROₓ. The percentages of the aforementioned substrate compositions are provided as mol percent (mol %) on an oxide basis measured within a band extending +/− twenty percent of ds4 from a centerline of substrate 910. In some embodiments, to enhance the structural integrity of the framework of majority-component material remaining after leaching minority components ROₓ, while also having an amount of ROₓ sufficient to generate a robust nanoporous network when leached, the original bulk SiO₂ content is 55% to 80% and the minority components ROₓ comprise 20% to 95%, or the original bulk SiO₂ content is 64% to 71%, and the minority components ROₓ comprise 29% to 36% of the bulk composition. In some embodiments, Al₂O₃ is one of the minority components ROₓ, and Al₂O₃ is the component having the highest mole percent (mol %) on an oxide basis after SiO₂.

Turning to FIG. 9b, an interim display device 901 includes a metal alloy layer 915 formed on surface 905 that at least partially enters into small openings 980 which are shown as partially filled openings 981. In some embodiments, metal alloy layer 915 is formed of an alloy of manganese (Mn) and copper (Cu). In some cases, the concentration of manganese in the alloy is less than ten (10) percent by mole percent (mol %). In other cases, the concentration of manganese in the alloy is less than five (5) percent by mole percent (mol %). In yet other cases, the concentration of manganese in the alloy is less than two (2) percent by mole percent (mol %).

In some embodiments, a thickness da4 of metal alloy layer 915 is less than one hundred, fifty (150) nanometers. In various embodiments, a thickness da4 of metal alloy layer 915 is less than one hundred (100) nanometers. In some embodiments, a thickness da4 of metal alloy layer 915 is less than fifty (50) nanometers. In various embodiments, thickness da4 of metal alloy layer 915 is less than thirty (30) nanometers. In one or more embodiments, thickness da4 of metal alloy layer 915 is less than twenty (20) nanometers. In some embodiments, thickness da4 of metal alloy layer 915 is between eight (8) and thirteen (13) nanometers. Formation of metal alloy layer 915 on substrate 910 may be done using any process for forming an alloy layer of less than fifty nanometers in thickness on a substrate. Such a process may include, but is not limited to, chemical vapor deposition.

Turning to FIG. 9c, an interim display device 902 includes a stop layer 920 formed over metal alloy layer 915. Stop layer 920 is formed by promoting the oxidation of metal alloy layer 915. Where metal alloy layer 915 is an alloy of manganese and copper, stop layer 920 is a manganese-copper oxide (MnCuOx) layer. The thickness of stop layer 920 is a small percentage of the thickness of metal alloy layer 915. In some embodiments, the oxidation of metal alloy layer 915 by incurring a vacuum break that allows oxygen to engage the exposed surface of the surface of metal alloy layer 915. In some cases, interim display device 901 may be exposed to an environment of pure oxygen or just an oxygen containing environment.

Turning to FIG. 9d, an interim display device 903 includes a material layer 925 formed on stop layer 920 of interim display device 902. In some embodiments, material layer 925 is substantially pure copper. Material layer 925 exhibits a thickness dc4 which is larger than thickness da4. In some embodiments, thickness dc4 of material layer 925 is greater than forty (40) times that of thickness da4 of metal alloy layer 915. In some embodiments, thickness dc4 of material layer 925 is greater than twenty (20) times that of thickness da4 of metal alloy layer 915. In various embodiments, thickness dc4 of material layer 925 is greater than five (5) times that of thickness da4 of metal alloy layer 915. In some embodiments, thickness dc4 of material layer 925 is greater than three (3) times that of thickness da4 of metal alloy layer 915. In one or more embodiments, thickness dc4 of material layer 925 is greater than two (2) times that of thickness da4 of metal alloy layer 915. Formation of material layer 925 on metal alloy layer 915 may be done using any process for forming a metal layer on an alloy layer. Such a process may include, but is not limited to, sputtering or chemical vapor deposition.

Turning to FIG. 9e, an interim display device 904 is formed by annealing interim display device 903. In some embodiments, the anneal is performed by exposing interim display device 903 to a temperature of greater than two hundred, eighty (200) degrees Celsius for more than one thousand (1000) seconds. In various embodiments, the anneal is performed by exposing interim display device 903 to a temperature of approximately three hundred (300) degrees Celsius for more than one thousand, five hundred (1500) seconds. In some embodiments, the anneal is performed by exposing interim display device 903 to a temperature of approximately three hundred, fifty (350) degrees Celsius for more than one thousand, five hundred (1500) seconds. During the anneal, one metal in the alloy of metal alloy layer 915 diffuses toward the surface of substrate 910 to form a thin interfacial layer 935 between substrate 910 and material layer 925, and leaving the other metal(s) in the alloy of metal alloy layer 915. Interfacial layer 935 exhibits a thickness dm3 that is a function of: thickness da3, the percentage of the out diffusing metal in the alloy of metal alloy layer 915, and the percentage of out diffusion achieved during the anneal.

Thus, in an embodiment where substrate 910 is an SiOₓ based substrate, metal alloy layer 915 is formed of a manganese-copper alloy, and material layer 925 is formed of substantially pure copper, the anneal results in diffusing the manganese of metal alloy layer 915 diffuses toward the surface of substrate 910 to form a thin layer of MnSiₓO_{y} (i.e., the metal-based oxide layer). Diffusing the manganese out of metal alloy layer 915 leaves copper that becomes part of material layer 925. The oxygen in stop layer 920 reduces the ability of manganese from metal alloy layer 915 to diffuse out into material layer 925. The copper oxide (CuOx) in stop layer 920 is reduced to copper by manganese diffusion from metal alloy layer 915 toward material layer 925. This results in an intervening layer 930 including a combination of manganese-oxide (MnOx), copper (Cu), and copper-oxide (CuOx) depending upon the diffusion and recombination achieved during the anneal. The thickness da4 of metal alloy layer 915 is approximately equal to a thickness dm6 of intervening layer 930 added to a thickness dm5 of interfacial layer 935. Using such a copper material layer and a manganese-copper alloy layer allows for the use of copper interconnects that offer low resistivity due to the substantial purity of the copper layer, and yet exhibits good adhesion to a glass or glass-ceramic substrate. The aforementioned use of a copper material layer and a manganese-copper alloy layer resulted in good copper interconnect adhesion to a Corning® Eagle XG® Slim Glass substrate, and a copper interconnect exhibiting lower resistivity than that achievable through use of a titanium or other metal adhesion layer formed between the substrate and the copper interconnect layer. Further, the aforementioned lower resistivity was achievable with a low concentration of manganese and a metal alloy layer 915 of less than one hundred (100) nanometers. Addition of the stop layer 920 results in intervening layer 930 that provides a good adhesion layer between material layer 925 and interfacial layer 935.

In conclusion, various novel systems, devices, methods and arrangements for edge electrodes. While detailed descriptions of one or more embodiments have been given above, various alternatives, modifications, and equivalents will be apparent to those skilled in the art without varying from the spirit of the invention. Therefore, the above description should not be taken as limiting the scope of the invention, which is defined by the appended claims.

1-33. (canceled)

34. A method for forming a metal interconnect on a substrate, the method comprising:
forming a manganese-copper layer over a surface of a substrate, wherein the substrate is formed of materials selected from a group consisting of: glass, ceramic, and a combination of glass and ceramic;
exposing a surface of the manganese-copper layer to an oxidizing environment to form an oxidized layer;
forming a copper layer disposed over the oxidized layer to yield an interim display device; and
annealing the interim display device to yield:
an interfacial layer including manganese-silicon-oxide adjacent the surface of the substrate, and
a layer including manganese-oxide between the interfacial layer and the copper layer.

35. The method of claim 34, wherein the concentration of manganese in the manganese-copper layer is less than five (5) percent measured as a mol percent.

36. The method of claim 34, wherein the copper layer is a substantially pure copper layer.

37. The method of claim 34, wherein the annealing includes exposing the interim display device to a temperature greater than two hundred eighty degrees Celsius for a period greater than two hundred seconds.

38. The method of claim 34, the method further comprising:
roughening a surface of the substrate to yield a roughened surface prior to forming the first copper layer over the surface of the substrate, wherein the roughening increases an exposed surface area when compared to an exposed surface area of a planar surface of the same dimension.

39. The method of claim 38, wherein roughening the surface of the substrate includes leaching the surface of the substrate.

40. The method of claim 38, wherein the substrate includes SiO₂, and wherein roughening the surface of the substrate includes etching the surface of the substrate such that the SiO2 concentration is higher near the interface of the substrate and the manganese-copper layer than the bulk of the substrate.

41. A display tile, the display tile comprising:
a substrate, wherein the substrate is formed of a material consisting of: glass, ceramic, and a combination of glass and ceramic;
a metal alloy layer disposed above a surface of the substrate; and
an interfacial layer of manganese-silicon-oxide disposed between the substrate and the metal alloy layer.

42. The display tile of claim 41, wherein the metal alloy layer is a substantially pure copper layer.

43. The display tile of claim 42, wherein the display tile further includes:
an intervening layer including manganese-oxide is sandwiched between the substantially pure copper layer and the interfacial layer.

44. The display tile of claim 41, wherein a thickness of the metal alloy layer is at least the same thickness of the interfacial layer.

45. The display tile of claim 44, wherein a thickness of the metal alloy layer is between five (5) nanometers and fifty (50) nanometers.

46. The display tile of claim 41, wherein the surface of the substrate exhibits openings extending below the surface of the substrate, and wherein material of the interfacial layer extends at least partially into the openings.

47. A method for forming a metal interconnect on a substrate, the method comprising:
roughening a surface of a substrate to yield a roughened surface; wherein the substrate is formed of materials selected from a group consisting of: glass, ceramic, and a combination of glass and ceramic; and wherein the roughening increases an exposed surface area when compared to an exposed surface area of a planar surface of the same dimension;
forming a copper alloy layer over the roughened surface, wherein the copper alloy layer includes copper and at least one other metal selected from a group consisting of: manganese, nickel, titanium, aluminum, zinc, magnesium, calcium, and tungsten;
forming a copper layer disposed above the copper alloy layer to yield an interim display device; and
annealing the interim display device such that at least a subset of the other metal combines with the glass of the substrate to yield an interfacial layer between the substrate and the copper layer.

48. The method of claim 47, wherein the other metal is manganese, and wherein the copper alloy layer is a manganese-copper alloy layer.

49. The method of claim 48, wherein the concentration of manganese in the manganese-copper alloy layer is less than five (5) percent measured as a mol percent.

50. The method of claim 48, wherein the interfacial layer includes manganese-silicon-oxide (MnSiOₓ).

51. The method of claim 48, wherein forming the copper layer disposed above the copper alloy layer is done in situ to avoid oxidation of the copper alloy layer.

52. The method of claim 48, the method further comprising:
oxidizing an exposed surface of the copper alloy layer prior to forming the copper layer, wherein annealing the interim display device yields the interfacial layer including manganese-silicon-oxide adjacent the surface of the substrate, and a layer including manganese-oxide between the interfacial layer and the copper layer.

53. The method of claim 47, wherein roughening the surface of the substrate includes leaching the surface of the substrate or etching the surface of the substrate.
